(19) United States
(12) Patent Application Publication
(10) Pub. No.: US 2006/0131645 A1
(43) Pub. Date: Jun. 22, 2006

(54) Semiconductor device and manufacturing method thereof

(75) Inventor: Mamoru Kaneko, Gunma (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/272,482

(22) Filed: Nov. 14, 2005

(30) Foreign Application Priority Data
Nov. 15, 2004 (JP) 2004-330162

(51) Int. Cl. H01L 29/94

(52) U.S. Cl. 257/330

(57) ABSTRACT

In the present invention, an npn junction or a pin junction is formed in an element peripheral part surrounding an element part. In addition, the same potential as that of a source electrode in the element part is applied, and a breakdown voltage of the element peripheral part is set to be always lower than that of the element part. Alternatively, resistance of the element peripheral part is lowered. Thus, breakdown always occurs in the element peripheral part, and the breakdown voltage becomes stable. Moreover, damage caused by breakdown can be prevented by eliminating occurrence of breakdown in a fragile gate oxide film. Furthermore, since the resistance is lowered, electrostatic breakdown strength is improved.

### BACKGROUND OF THE INVENTION

1. Field of the Invention

The present invention relates to a semiconductor device and a manufacturing method thereof, and more particularly relates to a semiconductor device capable of precisely controlling a breakdown voltage between drain and source, and a manufacturing method thereof.

2. Description of the Related Art

FIG. 21 shows a cross-sectional view of a conventional discrete semiconductor device. FIG. 21 shows a case of a MOSFET. In an element part 151, a MOS transistor 140 having a trench structure, for example, is provided. In a periphery of the element part 151, a guard ring 133 which is deeper than a channel layer 134 and has the same conductivity type as that of the channel layer 134 is provided to ease electric field concentration at a peripheral edge of the element part 151. Here, a region up to an end of the guard ring 133 indicated by the broken line is called the element part 151, and a region surrounding a periphery of the element part 151 is called an element peripheral part 150. Moreover, in order to apply a gate voltage to a gate electrode 143, polysilicon 143c is connected to a gate connection electrode 148.

With reference to FIG. 21, a method for manufacturing the conventional semiconductor device will be described.

In the MOSFET, a drain region 132 is formed by laminating an n⁻ type semiconductor layer on an n⁺ type silicon semiconductor substrate 131, and the like. By providing an opening in a part of an oxide film formed on the surface of the drain region 132, the p-type guard ring 133 is formed. Thereafter, the same p-type channel layer 134 is formed, and a trench 137 which penetrates the channel layer 134 and reaches the drain region 132 is formed.

Furthermore, an inner wall of the trench 137 is covered with a gate oxide film 141, and the gate electrode 143 made of polysilicon buried in the trench 137 is provided. Thereafter, a part of the polysilicon 143c is drawn out onto the substrate. In a surface of the channel layer 134 adjacent to the trench 137, an n⁺ type source region 145 is formed. Moreover, in the surface of the channel layer 134 between the source regions 145 of two cells adjacent to each other and in the periphery of the element part, p⁺ type body regions 144 are provided.

The gate electrode 143 is covered with an interlayer insulating film 146, and a source electrode 147 which comes into contact with the source region 145 and the body regions 144 is provided. Thus, the element part 151 is formed, in which a number of MOSFETs 140 are arranged. Moreover, when the source electrode 147 is formed, the gate connection electrode 148 is formed, which comes into contact with the polysilicon 143c. This technology is described for instance in Japanese Patent Application Publication No. 2004-31386 (see FIG. 4).

A breakdown voltage between drain and source (BVDS) of a MOS transistor is one of important device parameters to define performance and specifications of the transistor. In the discrete MOSFET as shown in FIG. 21, a value of the BVDS is basically determined by use of an impurity concentration ratio of a pn junction in the element part (active region) 151 of the transistor, in other words, an impurity concentration ratio of the channel layer 134 to the n⁻ type semiconductor layer 132. However, the impurity concentration of the channel layer 134 principally determines a threshold voltage of the transistor. Thus, the impurity concentration of the channel layer 134 cannot be freely changed.

Therefore, the value of the BVDS is controlled by use of the impurity concentration of the n⁻ type semiconductor layer (epitaxial layer) 132 and a thickness thereof as process parameters to determine the value of the BVDS.

Particularly, in the case of the MOS transistor having the trench structure, the gate electrode 143 penetrates the channel layer 134 and reaches the n⁻ type semiconductor layer 132. Thus, a breakdown mechanism becomes more complicated than that described above. Specifically, an actual value of the BVDS is influenced by not only the impurity concentration ratio of the channel layer 134 to the n⁻ type semiconductor layer 132 but also a depth and a shape of the trench 137 (the gate electrode 143). Thus, it is difficult to freely set the value of the BVDS.

Moreover, not only the value of the BVDS cannot be controlled with high accuracy but also it is uncertain in which portion of the element part 151 breakdown will occur.

Furthermore, it has been known that the guard ring 133 provided in the periphery of the channel layer 134 eases the electric field concentration at the peripheral edge of the element part 151 and is effective in securing a breakdown voltage. However, it has been found out that, if the guard ring 133 is provided, the BVDS becomes unstable under the influence of a junction breakdown voltage of the guard ring 133.

For example, when a voltage is applied between a drain and a source, a depletion layer spreads over the entire surface of a chip before breakdown, and initial breakdown occurs in the element part 151 positioned at the center of the chip. However, after breakdown, the depletion layer spreads in the guard ring 133 in a periphery of the chip. Thus, breakdown between the drain and the source finally occurs in the guard ring 133. Specifically, in the early stage of breakdown, the breakdown occurs in the element part 151 where the value of the BVDS is small. However, a breakdown position moves as the depletion layer spreads, and the breakdown is terminated in the guard ring 133. Accordingly, a phenomenon that the value of the BVDS fluctuates (hereinafter referred to as a creep phenomenon) occurs. Thus, there is a problem that breakdown voltage characteristics of the transistor become unstable.

### SUMMARY OF THE INVENTION

The present invention provides a semiconductor device that includes a semiconductor substrate, an element part that is part of the substrate and comprises a plurality of trench-type transistors, each of the transistors comprising a vertical cannel disposed between a source region formed in a surface of the substrate and a drain region that is disposed below the source region in the substrate, an element peripheral part that is part of the substrate and surrounds the element part, a peripheral impurity region that is disposed in the element peripheral part and has a same general conductivity type as the channel, and an electrode that is disposed on the peripheral impurity region and is electrically connected to the source regions.

The present invention also provides a method of manufacturing a semiconductor device. The method includes providing a semiconductor substrate of a first general conductivity type, defining an element part of the substrate in which a plurality of transistors are formed, forming an impurity region of a second general conductivity type in the substrate around the element part, and forming a peripheral electrode that is disposed on the impurity region and connected to electrodes of the transistors.

### BRIEF DESCRIPTION OF THE DRAWINGS

FIG. 1A is a plan view and FIG. 1B is a cross-sectional view showing a semiconductor device according to a first embodiment of the present invention.

FIGS. 2A and 2B are characteristic diagrams for explaining the semiconductor device according to the first embodiment of the present invention.

FIG. 3A is a plan view and FIG. 3B is a cross-sectional view showing a semiconductor device according to a second embodiment of the present invention.

FIG. 4 is a cross-sectional view showing a semiconductor device according to a third embodiment of the present invention.

FIGS. 5A and 5B are cross-sectional views showing the semiconductor device according to the third embodiment of the present invention.

FIG. 6A is a plan view and FIG. 6B is a cross-sectional view showing a semiconductor device according to a fourth embodiment of the present invention.

FIG. 7 is a cross-sectional view showing the semiconductor device according to the fourth embodiment of the present invention.

FIG. 8 is a characteristic diagram for explaining the semiconductor device according to the fourth embodiment of the present invention.

FIGS. 9A to 9C are characteristic diagrams for explaining the semiconductor device according to the first to fourth embodiments of the present invention.

FIGS. 10A to 10C are cross-sectional views showing a method for manufacturing a semiconductor device according to the first embodiment of the present invention.

FIGS. 11A to 11C are cross-sectional views showing the method for manufacturing a semiconductor device according to the first embodiment of the present invention.

FIGS. 12A to 12C are cross-sectional views showing the method for manufacturing a semiconductor device according to the first embodiment of the present invention.

FIGS. 13A and 13B are cross-sectional views showing the method for manufacturing a semiconductor device according to the first embodiment of the present invention.

FIGS. 14A to 14C are cross-sectional views showing a method for manufacturing a semiconductor device according to the second embodiment of the present invention.

FIG. 15 is a cross-sectional view showing a method for manufacturing a semiconductor device according to the third embodiment of the present invention.

FIGS. 16A to 16C are cross-sectional views showing a method for manufacturing a semiconductor device according to the fourth embodiment of the present invention.

FIGS. 17A to 17C are cross-sectional views showing the method for manufacturing a semiconductor device according to the fourth embodiment of the present invention.

FIGS. 18A to 18C are cross-sectional views showing the method for manufacturing a semiconductor device according to the second embodiment of the present invention.

FIGS. 19A to 19C are cross-sectional views showing the method for manufacturing a semiconductor device according to the third embodiment of the present invention.

FIGS. 20A to 20C are cross-sectional views showing the method for manufacturing a semiconductor device according to the fourth embodiment of the present invention.

FIG. 21 is a cross-sectional view showing a conventional semiconductor device and a manufacturing method thereof.

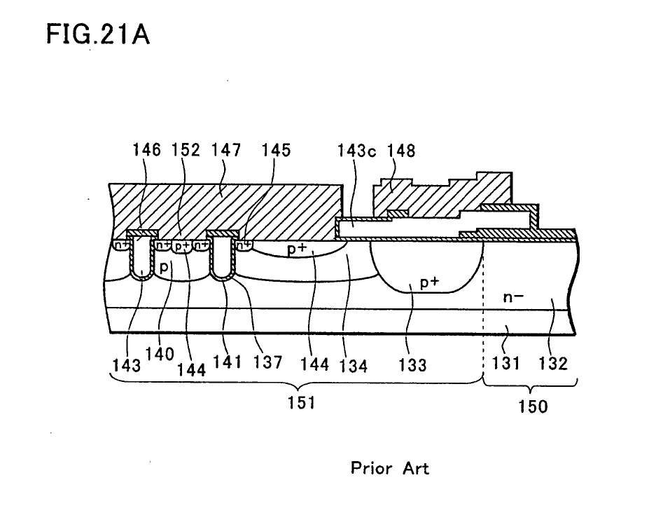

### DESCRIPTION OF THE EMBODIMENTS

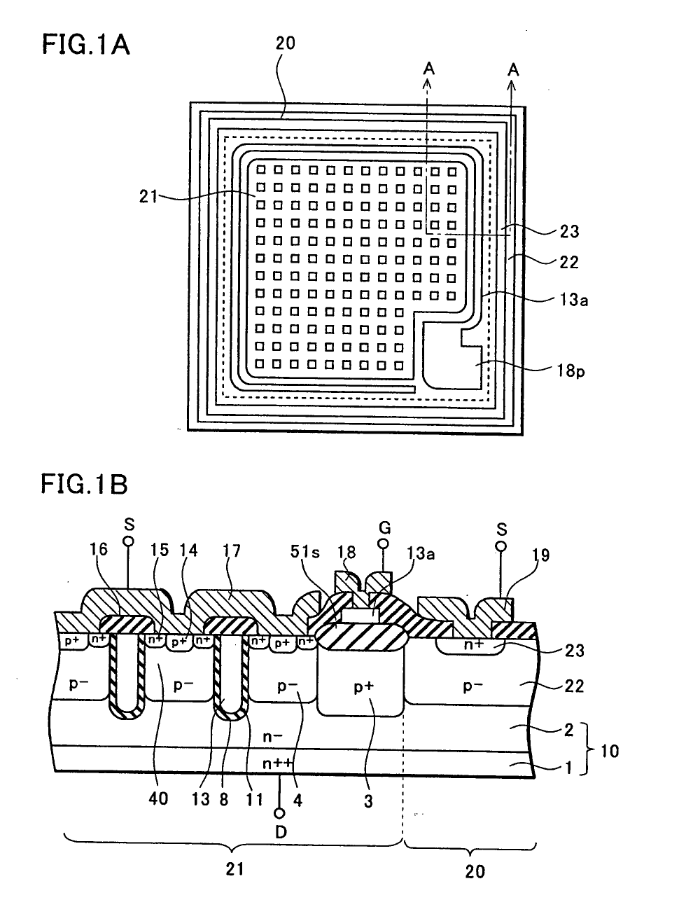

With reference to FIGS. 1 to 20, embodiments of the present invention will be described in detail by taking an n-channel trench MOSFET as an example.

With reference to FIGS. 1A and 1B, a first embodiment of the present invention will be described. FIGS. 1A and 1B show a structure of a semiconductor device according to the embodiment of the present invention. FIG. 1A is a schematic plan view of a chip, in which metal electrode layers such as a source electrode and a gate connection electrode are omitted. Moreover, FIG. 1B is an enlarged cross-sectional view along the line A-A.

The semiconductor device includes an element part 21 and an element peripheral part 20. In the element part 21 inside the broken line, a number of MOS transistors 40 are arranged. A first source electrode 17 is provided so as to be connected to a source region 15 of each of the MOS transistors 40 on the element part 21.

A gate electrode 13 of each of the MOS transistors 40 is extended to a peripheral edge of the element part 21 by a connection part 13a. The connection part 13a is connected to a gate pad electrode 18p through a gate connection electrode 18 provided on the connection part 13a. Thus, a gate voltage is applied to the MOS transistors 40.

In the element peripheral part 20 outside the broken line, a peripheral region 22 is provided. The peripheral region 22 is, for example, an opposite conductivity type region having approximately the same impurity concentration as that of a channel layer 4. In the first embodiment, a peripheral one conductivity type region 23 is provided in a surface of the peripheral region 22. Moreover, a second source electrode 19 is provided, which comes into contact with the peripheral one conductivity type region 23. The second source electrode 19 is electrically connected to the first source electrode 17, in other words, a source potential is applied to the second source electrode 19.

In this embodiment, a region up to an end of a guard ring 3 indicated by the broken line as described below is called the element part 21, and a region surrounding a periphery of the element part 21 is called the element peripheral part 20.

As shown in the cross-sectional view of FIG. 1B, a drain region 10 is obtained by providing an n⁻ type semiconductor layer 2, which is formed, for example, by laminating an epitaxial layer, on an n⁺ type silicon semiconductor substrate 1. The MOS transistors 40 are formed in the channel layer 4 provided in a surface of the drain region. The channel layer 4 is a diffusion region obtained by selectively injecting p-type impurities, for example, boron (B) into the surface of the drain region 10. An average impurity concentration of the channel layer 4 is approximately 1E17 cm⁻³. Here, an impurity concentration profile of each diffusion region is not necessarily constant. Therefore, in the following description, an average impurity concentration obtained by averaging impurity concentrations for each diffusion region will be used as the impurity concentration.

In a periphery of the channel layer 4, the guard ring 3 is provided, which comes into contact with the channel layer 4 and has an impurity concentration higher than that of the channel layer 4.

A trench 8 is formed to penetrate the channel layer 4 and reaching the drain region 10. Generally, the trench 8 is patterned to have a lattice shape or a stripe shape on the semiconductor layer 2. A gate oxide film 11 is provided on an inner wall of the trench 8, and polysilicon is buried therein to form the gate electrode 13.

The gate oxide film 11 is provided to have a thickness of several hundred A according to a drive voltage on the inner wall of the trench 8, which comes into contact with at least the channel layer 4. Since the gate oxide film 11 is an insulating film, the gate oxide film 11 is sandwiched between the gate electrode 13 provided in the trench 8 and the semiconductor layer 2. Thus, a MOS structure is formed.

The gate electrode 13 is provided by burying a conductive material in the trench 8. The conductive material is, for example, polysilicon, and n-type impurities are introduced into the polysilicon in order to reduce a resistance. The gate electrode 13 is drawn out onto the semiconductor layer 2 by the connection part 13a and comes into contact with the gate connection electrode 18 which surrounds the periphery of the drain region 10.

The gate electrode 13 is provided so as to come into contact with the channel layer 4 through the gate insulating film 11.

The source region 15 is a diffusion region obtained by injecting n⁺ type impurities into a surface of the channel layer 4 adjacent to the gate electrode 13, and comes into contact with the first source electrode 17 which covers the element part 21 and is made of metal. Moreover, in the surface of the channel layer 4 between the source regions 15 adjacent to each other, a body region 14 which is a diffusion region of p⁺ type impurities is provided to stabilize a potential of the substrate. Thus, a portion surrounded by the trenches 8 adjacent to each other becomes a cell of one MOS transistor 40. A number of these cells are gathered to form the element part 21.

The first source electrode 17 is a metal electrode patterned to have a desired shape by sputtering aluminum or the like and is provided through an interlayer insulating film 16. The first source electrode 17 covers the element part 21 and comes into contact with the source region 15 and the body region 14.

In the element peripheral part 20, the peripheral region 22 is provided. The peripheral region 22 is formed to have an impurity concentration according to a desired breakdown voltage (breakdown voltage between drain and source: BVDS). As an example, in this embodiment, the peripheral region 22 has an average impurity concentration of about 1E17 cm⁻³, which is approximately the same as that of the channel layer 4. Moreover, high concentrations (n⁺) of n-type impurities (arsenic or the like), as much as those in the source region 15, are ion-implanted into a surface of the peripheral region 22. Thus, a peripheral n-type region 23 is provided, which has an impurity concentration of about 1E20 to 1E21 cm⁻³. The second source electrode 19 to be electrically connected to the first source electrode 17 comes into contact with the peripheral n-type region 23.

As described above, by providing the peripheral n-type region 23 having a high impurity concentration in the surface of the peripheral region 22, an n⁺/p⁻/n⁻ (/n⁺⁺) junction (hereinafter referred to as an npn junction in this embodiment) can be formed in the element peripheral part 20. Moreover, in the element part 21, a p⁻/n⁻ (/n⁺⁺) junction (hereinafter referred to as a pn junction) is formed by the channel layer 4 and the n⁻ type semiconductor layer 2.

The peripheral region 22 has approximately the same impurity concentration as that of the channel layer 4. As described above, the impurity concentration of the peripheral region 22 is selected according to the desired breakdown voltage. Meanwhile, by setting the impurity concentration of the peripheral region 22 to be approximately the same as that of the channel layer 4, the npn junction in the element peripheral part 20 can be set to have a breakdown voltage lower than that of the pn junction in the element part 21.

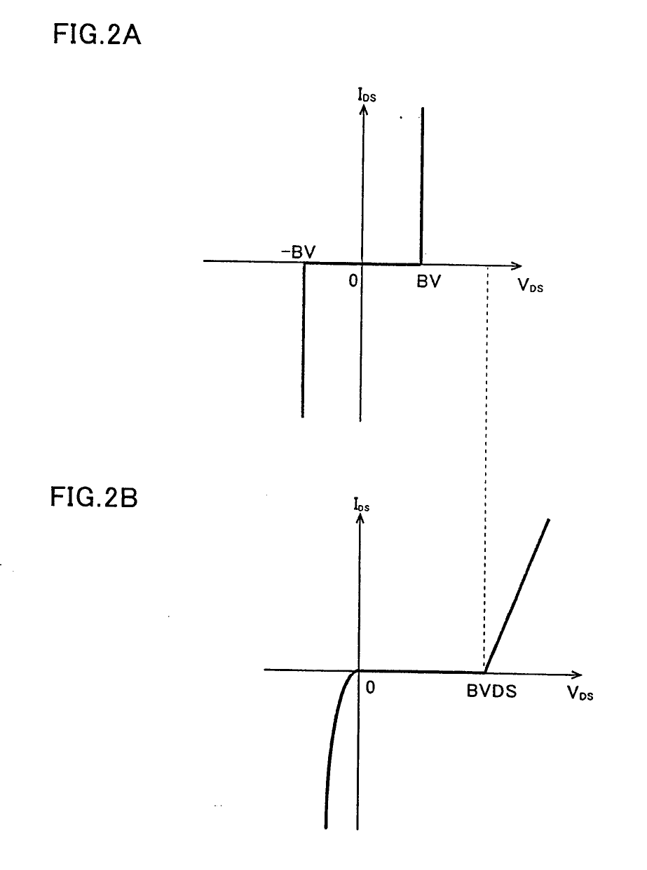

Here, FIGS. 2A and 2B show a comparison of I-V characteristics at the time of breakdown between the npn junction and the pn junction when the p-type regions have approximately the same impurity concentration. FIG. 2A shows breakdown characteristics of the npn junction, and FIG. 2B shows breakdown characteristics of the pn junction.

As shown in FIGS. 2A and 2B, if the p-type regions have approximately the same impurity concentration, a breakdown voltage (BV) of the npn junction will be lower than a breakdown voltage (BVDS) of the pn junction.

Moreover, a rise of the I-V characteristics of the npn junction is steeper than that of the pn junction, and a resistance of a drain current at the time of breakdown can be set close to 0. Therefore, after breakdown, the drain current can flow at a low resistance. Thus, an electric energy is unlikely to be converted into a heat energy.

This is the same as the case that no heat is generated even if a large current flows into a superconducting material since there is no electric resistance. In the npn junction, heat generation is reduced at the time of breakdown. Thus, the protection against electric overload can be improved.

In this embodiment, the impurity concentration of the peripheral region 22 is approximately the same as that of the channel layer 4, and the impurity concentration of the peripheral n-type region 23 is approximately the same as that of the source region 15.

Therefore, the breakdown voltage (of the npn junction) between the peripheral n-type region 23 and the n⁻ semiconductor layer 2 in the element peripheral part 20 can be always set lower than the breakdown voltage (of the pn junction) between the source region 15 and the drain region 10 in the element part 21.

Thus, in the structure described above, initial breakdown always occurs in the element peripheral part 20. Moreover, the breakdown position never changes until the breakdown terminates. Therefore, it is possible to avoid a creep phenomenon in which the breakdown position moves, and to obtain stable breakdown characteristics. Moreover, in the case where the peripheral region 22 is formed outside the guard ring 3, the impurity concentrations of the channel layer 4 and the peripheral region 22 can be selected individually. Therefore, a breakdown voltage of the MOSFET can be precisely controlled without affecting the element part 21.

The breakdown of the element part 21 is essentially not a physical breakdown but a phenomenon which can be repeated by returning a bias. However, the gate oxide film 11 is thin and fragile, and a current is limited, which may lead to a physical breakdown due to Joule heat. Specifically, also from the above perspective, it is advantageous that, by guiding the breakdown of the element part 21 to the element peripheral part 20, the electric field concentration can be controlled so as not to cause breakdown in the region where the fragile gate oxide film 11 is disposed.

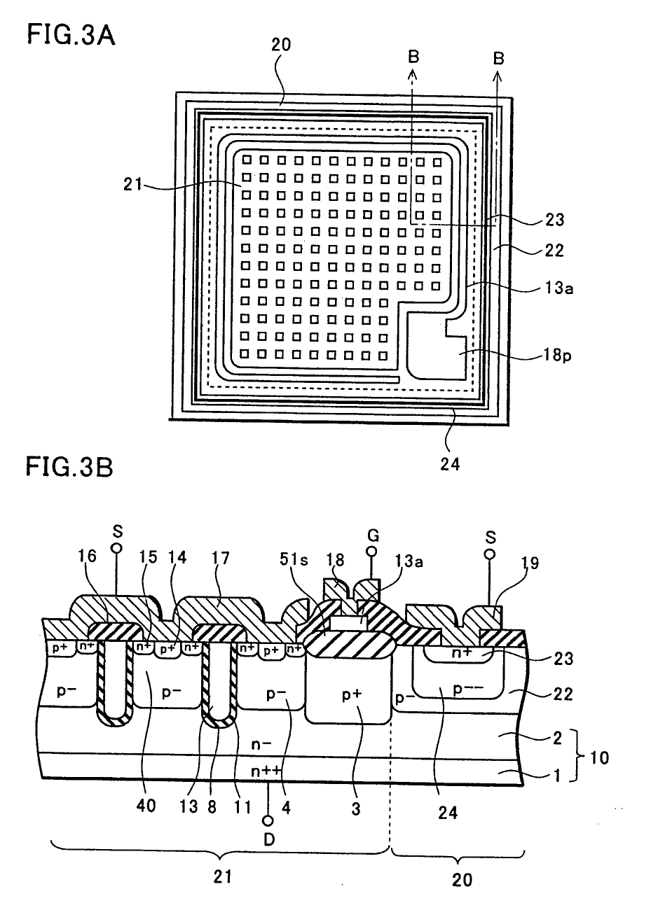

FIGS. 3A and 3B show a second embodiment. FIG. 3A is a plan view, and FIG. 3B is a cross-sectional view along the line B-B in FIG. 3A. Note that, since the plan view is approximately the same as that shown in FIG. 1A, description thereof will be omitted. Moreover, since the element part 21 is also the same as that in the first embodiment, description thereof will be omitted.

In the second embodiment, a first opposite conductivity type region 24 having an impurity concentration lower than that of a peripheral region 22 is provided in the peripheral region 22.

A breakdown voltage of an npn junction is determined mainly based on an impurity concentration of a p layer. The lower the impurity concentration of the p layer, the more the breakdown voltage increases. Accordingly, in the structure of the first embodiment (FIGS. 1A and 1B), if it is requested to increase the breakdown voltage (BVDS), counter doping is performed to form a first p-type region 24 having a concentration lower (p⁻⁻) than that of the peripheral region 22. Thus, the impurity concentration of the p layer in the npn junction is reduced, and the BVDS is increased. Note that, also in this case, the first p-type region 24 has such an impurity concentration as to set the BVDS lower than that of a channel layer 4.

Also in the second embodiment, the npn junction is formed in an element peripheral part 20 by the peripheral region 22, the first p-type region 24 and a peripheral n-type region 23. Moreover, characteristics of the npn junction are approximately the same as those shown in FIG. 2A. Specifically, by setting a breakdown voltage lower than that in the element part 21, breakdown can be guided to the element peripheral part 20. Moreover, in the second embodiment, the breakdown voltage of the element peripheral part 20 can be set higher than that in the first embodiment.

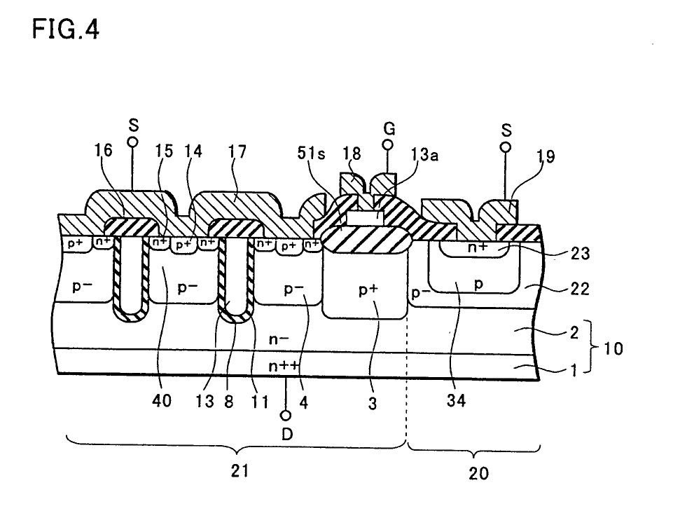

FIG. 4 shows a third embodiment. A plan view is the same as that shown in FIG. 3A, and FIG. 4 shows a cross-sectional view along the line B-B.

In the third embodiment, a second opposite conductivity type region 34 having an impurity concentration higher than that of a peripheral region 22 is provided in the peripheral region 22.

In the case where a MOSFET is required to have a breakdown voltage (of 5V or lower) which conforms to an LSI or the case where a MOSFET is desired to have a breakdown voltage of 2 to 3V in accordance with an LSI having a low power supply voltage, a breakdown voltage of an element peripheral part 20 has to be set lower than a breakdown voltage of a gate oxide film.

In such a case, it is better to provide a second p-type region 34, which has the impurity concentration higher than that of a channel layer 4. Thus, an impurity concentration of a p layer in an npn junction can be increased, and the breakdown voltage of the element peripheral part 20 can be lowered.

In the case where p-type regions have approximately the same impurity concentration, there is a sufficient difference of about over ten V to several ten V, for example, between a breakdown voltage of a pn junction and that of the npn junction. Therefore, the breakdown voltage can be freely designed by changing the impurity concentration of the element peripheral part 20 (npn junction) as long as the voltage does not reach a breakdown voltage of an element part 21 (pn junction).

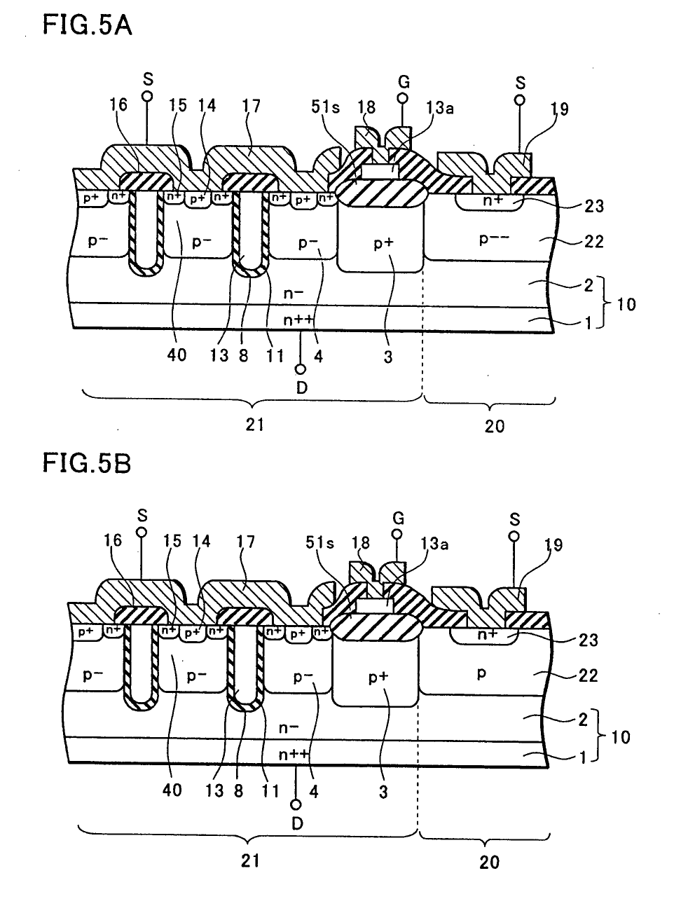

Note that, as shown in FIGS. 5A and 5B, the impurity concentration of the peripheral region 22 may be set different from that of the channel layer 4. FIG. 5A shows the peripheral region 22 having an impurity concentration lower than that of the channel layer 4, and FIG. 5B shows the peripheral region 22 having an impurity concentration higher than that of the channel layer 4.

In the first embodiment, the peripheral region 22 and the peripheral n-type region 23 can be formed by utilizing a process of manufacturing the element part 21 (to be described later). However, as in the case of the second and third embodiments, if the breakdown voltage of the element peripheral part 20 is controlled, the impurity concentration of the peripheral region 22 is changed by use of the first and second p-type regions 24 and 34. Specifically, the same effect can be achieved even if the impurity concentration of the peripheral region 22 itself is set so as to have a desired breakdown voltage as shown in FIGS. 5A and 5B.

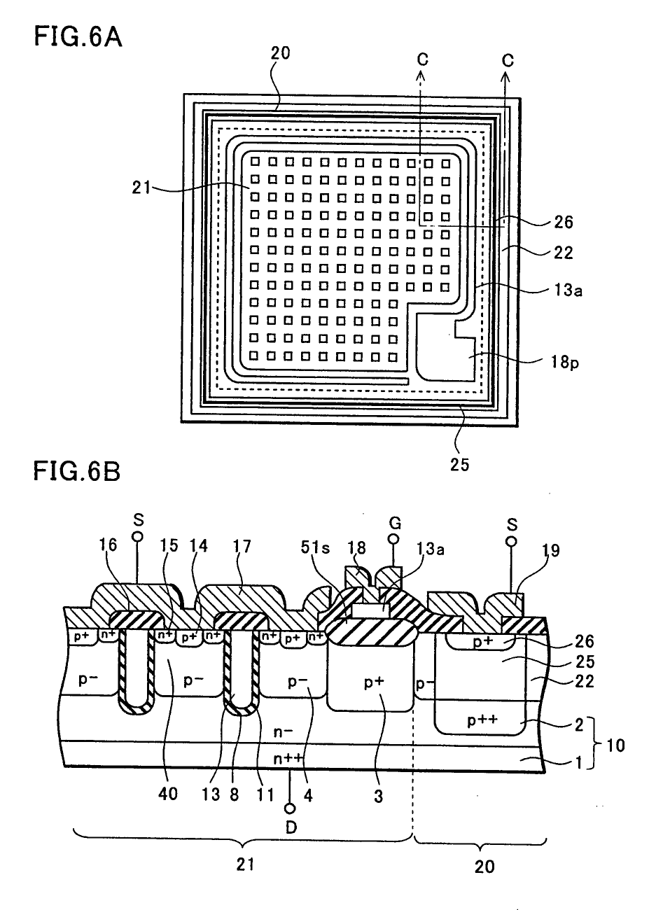

FIGS. 6A and 6B show a fourth embodiment. FIG. 6A is a plan view, and FIG. 6B is a cross-sectional view along the line C-C in FIG. 6A. Note that, since the plan view is approximately the same as that shown in FIG. 1A, description thereof will be omitted. Moreover, since an element part 21 is also the same as that in the first embodiment, description thereof will be omitted.

In the fourth embodiment, an opposite conductivity type region having a high impurity concentration is formed at a deep position of a drain region 10. Specifically, a peripheral opposite conductivity type region 25, which is deeper than a peripheral region 22 and reaches an n⁻ type semiconductor layer 2 and having a high impurity concentration (p⁺⁺), is formed inside the peripheral region 22.

A peripheral p-type region 25 is, for example, a region which has an impurity concentration higher than those of a channel layer 4 and a guard ring 3 and has an impurity concentration of about 1E20 to 1E21 cm⁻³. In a surface of the peripheral p-type region 25, a source contact region 26 is provided, which comes into contact with a second source electrode 19. Since the source contact region 26 forms an ohmic contact with the second source electrode 19, the source contact region 26 is described as p⁺. However, a surface impurity concentration of the peripheral p-type region 25 is about 1E20/cm³. Specifically, the source contact region 26 actually has approximately the same impurity concentration (p⁺⁺) as that of the peripheral p-type region 25.

As described above, by forming the p-type region having a high impurity concentration at the deep position of the drain region 10, the n⁻ type semiconductor layer 2 becomes intrinsic. Thus, an n⁺⁺/n⁻/p⁺⁺(/p⁺) junction (hereinafter referred to as a tunnel junction in the present specification) is formed, which is close to a pin junction.

The tunnel junction is a pn junction having a high impurity concentration and has a low electric resistance. Therefore, by adopting the structure of the fourth embodiment, a resistance of the element peripheral part 20 can be set lower than that of the element part 21, and a breakdown position can be guided to the element peripheral part 20.

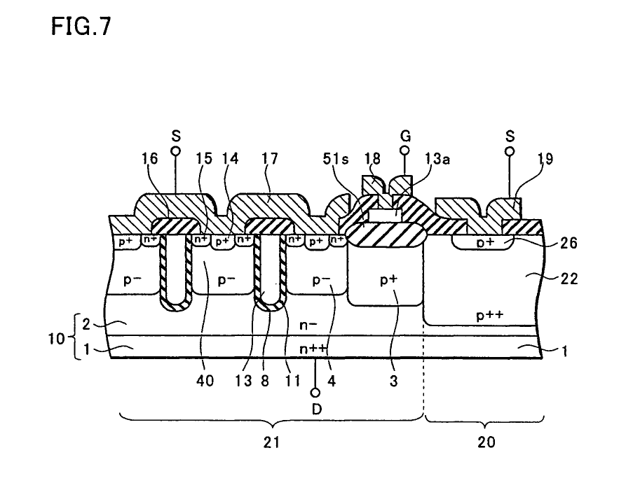

Note that, as shown in FIG. 7, the tunnel junction may be formed by setting the impurity concentration of the peripheral region 22 higher than that of the channel layer 4 and allowing deeper diffusion. In this case, the same effect as that shown in FIGS. 6A and 6B can also be achieved.

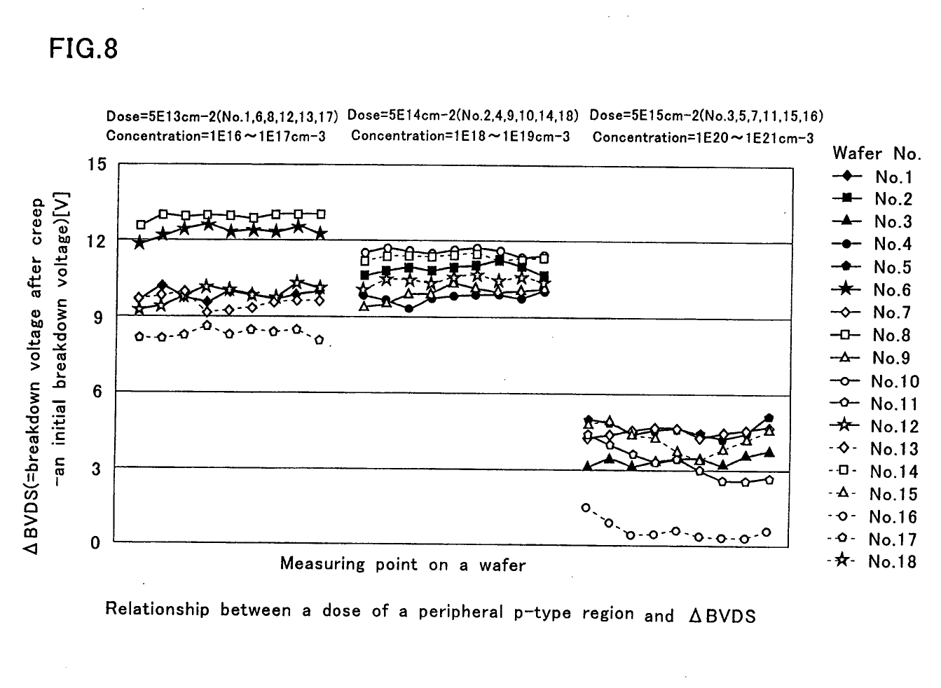

FIG. 8 is a graph showing a relationship between a dose of the peripheral p-type region 25 (the peripheral region 22 in the case of FIG. 7) and ΔBVDS in the fourth embodiment. The horizontal axis of the graph is a measuring point on a wafer.

ΔBVDS is a difference between a breakdown voltage in a state where breakdown is stable and an initial breakdown voltage. The smaller the difference is, the fewer the fluctuations.

As to 18 wafers (No. 1 to 18) in which the peripheral p-type region 25 is formed by use of 3 kinds of doses, ΔBVDS at each of 9 measuring points in the wafers is measured.

As shown in the graph, in the case of the fourth embodiment, a variation in ΔBVDS within the wafers is small in all cases. Thus, it can be said that characteristics become stable. Furthermore, it is understood that the larger the dose is (on the right side), the smaller the value of ΔBVDS and the fewer the fluctuations.

The breakdown voltage is determined by a position where breakdown occurs. Thus, if the position where the breakdown occurs differs, the breakdown voltage becomes unstable. For example, if the breakdown is started from the element part 21 and a current path is changed from the element part 21 to the element peripheral part 20, the breakdown voltage never takes a fixed value.

As in the case of this embodiment, by setting a resistance of the element peripheral part 20 lower than that of the element part 21 and guiding breakdown to a desired position (the element peripheral part 20), there will be no change in the breakdown voltage as shown in FIG. 8.

Furthermore, the tunnel junction of a pin type has a small junction breakdown voltage and a small electric resistance. Thus, the protection against electric overload such as overcurrent, overvoltage and static electricity can be improved.

In these embodiments, the protection against electric overload can be improved in any of the first to fourth embodiments, in other words, the electrostatic breakdown becomes high.

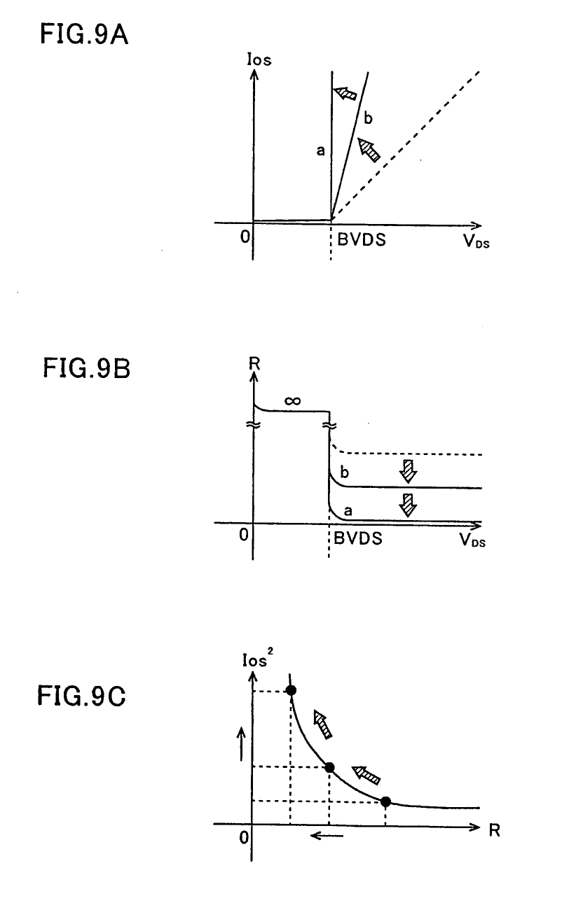

With reference to FIGS. 9A to 9C, the reason for the above will be described.

FIG. 9A shows I-V characteristics indicating a change in a breakdown current Ios in the case where a voltage to be an overstress is gradually applied. FIG. 9B is a graph showing a relationship between a resistance value R and a voltage in FIG. 9A. In FIGS. 9A and 9B, the broken line indicates the case of the pn junction such as the element part 21, the solid line “a” indicates the case of the npn junction in the first to third embodiments, and the solid line “b” indicates the case of the tunnel junction (pin junction) in the fourth embodiment.

As shown in FIG. 9A, the npn junction in the first to third embodiments has the steepest increase in current after breakdown, the tunnel junction of the fourth embodiment has the second steepest increase, and the pn junction such as the element part 21 has the most gradual increase.

In this case, as to a relationship between a resistance R and a BVDS, as shown in FIG. 9B, all the junctions show high impedance before breakdown. However, after breakdown, the impedance gets higher in the order of the npn junction, the tunnel junction and the pn junction. As described below, lowering of the resistance enables the overcurrent Ios up to breakdown to be increased. Specifically, time for reaching a breakdown energy of a device is extended, and the device becomes less susceptible to breakdown.

First, description will be given of the case where a semiconductor device is electrically broken down. A main cause of electrical breakdown of the semiconductor device is heat energy. As to a basic mechanism of the electrical breakdown, heat generation causes breakdown of a crystal lattice or dielectric breakdown of an insulating film such as a gate oxide film. In the case of a MOS device, assuming that an energy to break down the device is a power P, the power P can be expressed as P [J/s]=P [W]=current [A]×voltage [V].

When the above is applied to the case where a crystal is broken down, the voltage is controlled by a breakdown voltage (BVDS) in all cases (FIG. 9B). Thus, the current becomes a variable, and, as a result, application of the overcurrent Ios breaks down the device.

Moreover, in the case of the dielectric breakdown of the gate oxide film, the voltage is controlled by an oxide film breakdown voltage (gate oxide film breakdown voltage: BVox). Thus, the current becomes a variable, and, as a result, application of the overcurrent Ios breaks down the device.

Therefore, the energy to destroy the device is expressed as the power Pos=Ios×BVDS or Pos=Ios×BVox. Moreover, since P=I×E=I×(I×R), in I×I=P/R, when the destruction energy Pos is constant, (Ios)²=Pos/R is established. Specifically, the breakdown current Ios can be increased along with a reduction in the resistance value R, as indicated by the arrow in FIG. 9C, by the npn junction or the pin junction in this embodiments. Thus, the device becomes less susceptible to breakdown.

Next, description will be given of device breakdown between drain and source. The BVDS is a pn junction breakdown voltage and, at the same time, indicates an electric breakdown strength at the time of breakdown. Moreover, the tunnel junction also has the same principle as a realistic device. Specifically, in the first to fourth embodiments, the BVDS indicates the electric resistance at the time of breakdown.

By the electric resistance, electric energy is converted into heat energy, and the device generates heat. When an amount of heat generated exceeds a certain limit, an aluminum electrode having a low melting point starts to melt. The melted aluminum merges into the silicon substrate to cause junction destruction between drain and source. In order to avoid the junction destruction, reducing the resistance R at the time of breakdown is effective.

In the first to third embodiments, by forming the npn junction in the element peripheral part 20, the resistance R at the time of breakdown can be reduced to be smaller than that of the pn junction in the element part 21. Thus, the junction breakdown can be avoided.

Also in the fourth embodiment, by forming the pin junction in the element peripheral part 20, the resistance R of the current flowing therein can be reduced to be smaller than that of the pn junction in the element part 21. In other words, the junction breakdown can be avoided.

Therefore, in this embodiment, the current value Ios leading to an electrostatic breakdown voltage can be increased to be larger than that in the conventional case. Thus, a high electrostatic breakdown protection can be obtained. Moreover, in the case where the first to third embodiments are compared to the fourth embodiment, it is understood that the npn junction has the smallest resistance value and the first to third embodiments are more effective than the fourth embodiment.

For example, assuming that the resistance of the pn junction in the element part 21 is 1, the resistance of the pin junction of the element peripheral part 20 in the fourth embodiment will be approximately 0.5, and the resistance of the npn junction of the element peripheral part 20 in the first to third embodiments will be approximately 0.3.

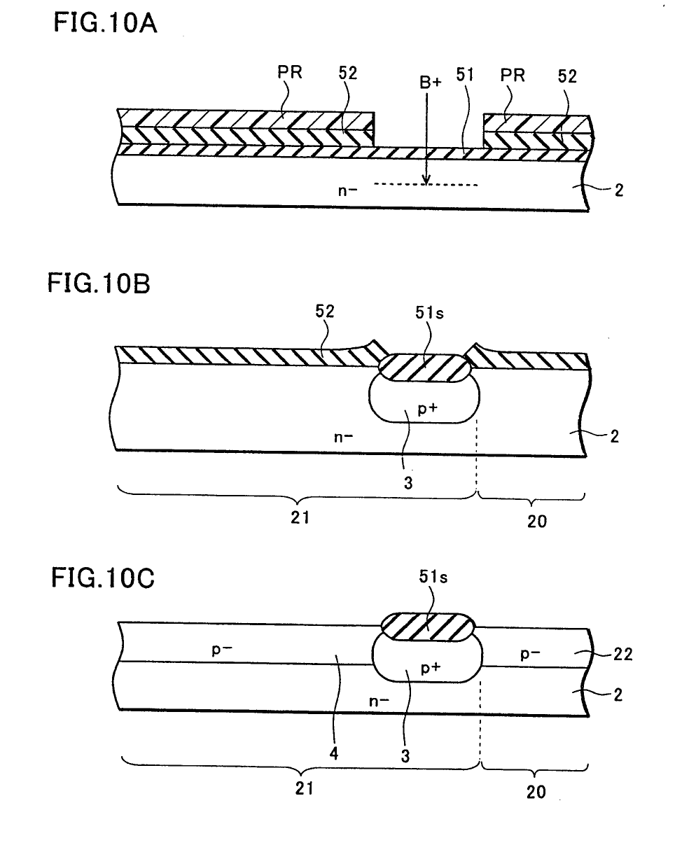

Next, FIGS. 10 to 20 show a method for manufacturing a semiconductor device according to the embodiments of the present invention by taking an n-channel MOSFET as an example.

First, FIGS. 10 to 13 show the case of a first embodiment.

A method for manufacturing a semiconductor device of the first embodiment is a method for manufacturing a semiconductor device in which an element part having MOS transistors disposed therein and an element peripheral part surrounding a periphery of the element part are formed. The method includes the steps of: forming a channel layer having an opposite conductivity type on a surface of a one conductivity type semiconductor substrate to be a drain region of the element part, and forming a peripheral region having an opposite conductivity type in the element peripheral part; forming a gate electrode which comes into contact with the channel layer with an insulating film interposed therebetween; forming a source region having one conductivity type in a surface of the channel layer adjacent to the gate electrode, and forming a peripheral one conductivity type region in a surface of the peripheral region; and forming a first electrode which comes into contact with the source region, and a second electrode which comes into contact with the peripheral one conductivity type region and is electrically connected to the first electrode.

First step (FIGS. 10A to 10C): forming a channel layer having an opposite conductivity type on a surface of a one conductivity type semiconductor substrate to be a drain region of the element part, and forming a peripheral region having an opposite conductivity type in the element peripheral part.

A drain region 10 is formed by providing an n⁻ type semiconductor layer, which is formed, for example, by laminating an epitaxial layer, on an n⁺ type silicon semiconductor substrate 1 (not shown). Thereafter, an oxide film 51 and a nitride film 52 are provided on the entire surface, and a mask having an opening in the nitride film 52 is formed. Specifically, the opening is provided in a region of the nitride film 52 where a guard ring is to be formed by use of a photo resist PR. Subsequently, p-type impurities (for example, boron (B)) are ion-implanted by an injection energy of 50 KeV and a dose of 1E15 to 2E15 cm⁻² (FIG. 10A).

After removing the resist PR, heat treatment is performed to form a LOCOS oxide film 51s in the opening, and boron is diffused to form a guard ring 3 (FIG. 10B). In this embodiment, as described above, a region inside the guard ring 3 becomes an element part 21 in which MOS transistors are disposed, and a region outside the guard ring 3 becomes an element peripheral part 20.

Furthermore, the nitride film 52 is removed, and boron, for example, is ion-implanted into the entire surface by an injection energy of 50 KeV and a dose of 1E13 to 3E13 cm⁻². Thereafter, heat treatment is performed at about 1100° C., and boron is diffused to form a channel layer 4 in a surface of the semiconductor layer 2 in the element part 21. In this event, a p-type peripheral region 22 which comes into contact with the guard ring 3 is simultaneously formed in the element peripheral part 20. Specifically, the peripheral region 22 is formed by the same step as that of the channel layer 4 and has approximately the same impurity concentration as that of the channel layer 4 (FIG. 10C).

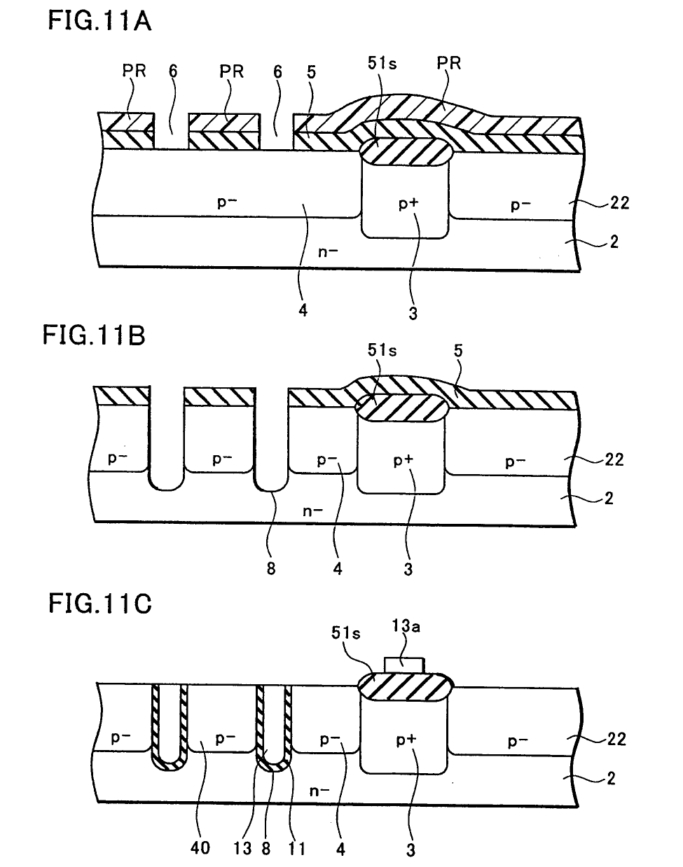

Second step (FIGS. 11A to 11C): forming a gate electrode which comes into contact with the channel layer with an insulating film interposed therebetween.

By use of a CVD method, a CVD oxide film 5 made of NSG (non-doped silicate glass) is formed on the entire surface. Thereafter, a mask made of a resist film is provided over the entire surface except for a portion to be an opening of a trench. Subsequently, the CVD oxide film 5 is partially removed by dry etching to form a trench opening 6 in which the channel layer 4 is exposed (FIG. 11A).

Thereafter, by using the CVD oxide film 5 as a mask, the silicon semiconductor layer 2 under the trench opening 6 is dry-etched by CF gas and HBr gas. Thus, a trench 8 is formed, which penetrates the channel layer 4 and reaches the drain region 10 (FIG. 11B).

Subsequently, dummy oxidation is performed to form an oxide film (not shown) on an inner wall of the trench 8 and a surface of the channel layer 4, and etching damage in dry etching is removed. Thereafter, the oxide film and the CVD oxide film 5 are removed by etching.

Furthermore, the entire surface is subjected to oxidation, and a gate oxide film 11 is formed to have a thickness of, for example, about 300 to 700 Å, according to a drive voltage, on the inner wall of the trench 8. Thereafter, a polysilicon layer is deposited on the entire surface, a mask which leaves a connection part 13a is provided, and the entire surface is dry-etched. The polysilicon layer may be a layer formed by depositing polysilicon including impurities or a layer into which impurities are introduced after non-doped polysilicon is deposited. Thus, a gate electrode 13 buried in the trench 8 and the connection part 13a are formed (FIG. 11C).

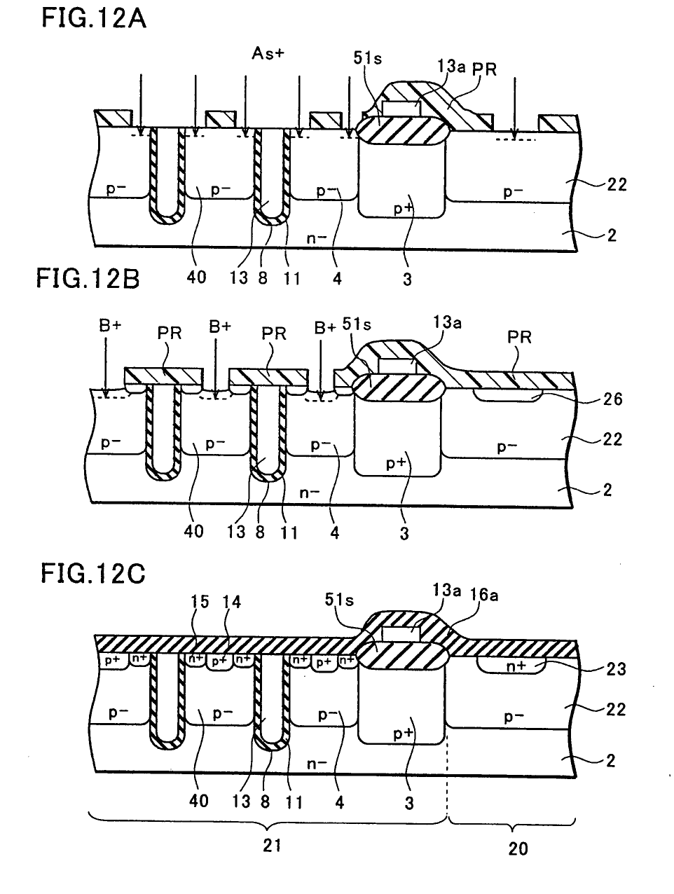

Third step (FIGS. 12A to 12C): forming a source region having one conductivity type in a surface of the channel layer adjacent to the gate electrode, and forming a peripheral one conductivity type region in a surface of the peripheral opposite conductivity type region.

A mask made of a resist PR, in which formation regions of a source region and a peripheral n-type region are exposed, is formed, and n-type impurities (for example, arsenic (As)) are ion-implanted into the entire surface by an injection energy of 140 KeV and a dose of 5E15 to 6E15 cm⁻². In this event, the n-type impurities are simultaneously ion-implanted into a surface of the peripheral region 22 (FIG. 12A).

Subsequently, a mask made of a resist PR, in which a formation region of a body region is exposed, is formed, and p-type impurities (for example, boron (B)) are ion-implanted by an injection energy of 40 KeV and a dose of 2E15 to 5E15 cm⁻² (FIG. 12B).

Thereafter, a BPSG (boron phospho silicate glass) layer 16a to be an interlayer insulating film is deposited to have a thickness of about 6000 Å on the entire surface and is reflowed at about 900° C. This heat treatment diffuses the n-type impurities and the p-type impurities, respectively, to form a source region 15 adjacent to the trench 8, at the same time, a body region 14 between the source regions 15 is formed. Moreover, at the same time, a high-concentration peripheral n-type region 23 is formed in the peripheral region 22. Note that the ion implantations for the source region 15 and the body region 14 are not limited to the order described above but may be switched.

Thus, a region surrounded by the trench 8 becomes a cell of a MOS transistor 40, and the element part 21 in which a number of the cells are arranged is formed. In the element part 21, a pn junction is formed by the channel layer 4 and the n⁻ type semiconductor layer 2.

Moreover, in the element peripheral part 20 on the periphery of the element part 21, an npn junction is formed by the substrate (not shown), the n⁻ type semiconductor layer 2, the peripheral region 22 and the peripheral n-type region 23 (FIG. 12C).

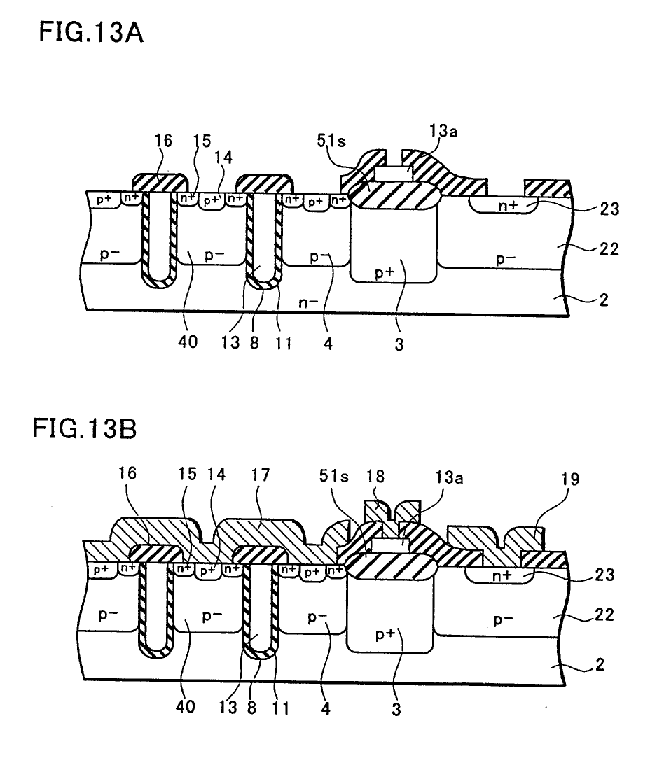

Fourth step (FIGS. 13A and 13B): forming a first electrode which comes into contact with the source region, and a second electrode which comes into contact with the peripheral one conductivity type region and is electrically connected to the first electrode.

A mask made of a resist PR having an opening in a predetermined pattern is provided on the BPSG layer 16, and etching is performed. Thereafter, reflow is performed at about 900° C. to form an interlayer insulating film 16 (FIG. 13A).

Thereafter, aluminum or the like is deposited on the entire surface by use of a sputtering apparatus and is patterned to have a desired shape. Thus, a first source electrode 17 is formed, which covers the entire surface of the element part 21 and comes into contact with the source region 15 and the body region 14. At the same time, a gate connection electrode 18 is formed, which is provided on the connection part 13a and comes into contact with the connection part 13a. Furthermore, a second source electrode 19 which comes into contact with the peripheral n-type region 23 is formed by use of the same metal layer. The second source electrode 19 is electrically connected to the first source electrode 17 (FIG. 13B).

The first source electrode 17 is connected to the second source electrode 19. Accordingly, when a predetermined drain voltage is applied to a drain electrode (not shown), the element part 21 operates as an np junction diode and the element peripheral part 20 operates as an npn junction diode.

When a predetermined BVDS is reached, breakdown occurs in the element peripheral part 20 having a low breakdown voltage. This is because, as described above, the peripheral region 22 has approximately the same impurity concentration as that of the channel layer 4, and, under this condition, an npn junction is formed in the element peripheral part 20 and an np junction is formed in the element part 21.

Thereafter, in the state described above, the breakdown is terminated. Therefore, in this embodiment, by forming the npn junction in the element peripheral part 20, the breakdown occurs in the element peripheral part 20 from the beginning to the end, and there will be no change in a breakdown position.

Moreover, as described above, only by changing the masks for forming the channel layer 4 and the source region 15, the semiconductor device can be manufactured by utilizing a conventional process. Therefore, BVDS characteristics can be stabilized without increasing the number of masks or increasing the steps of the process.

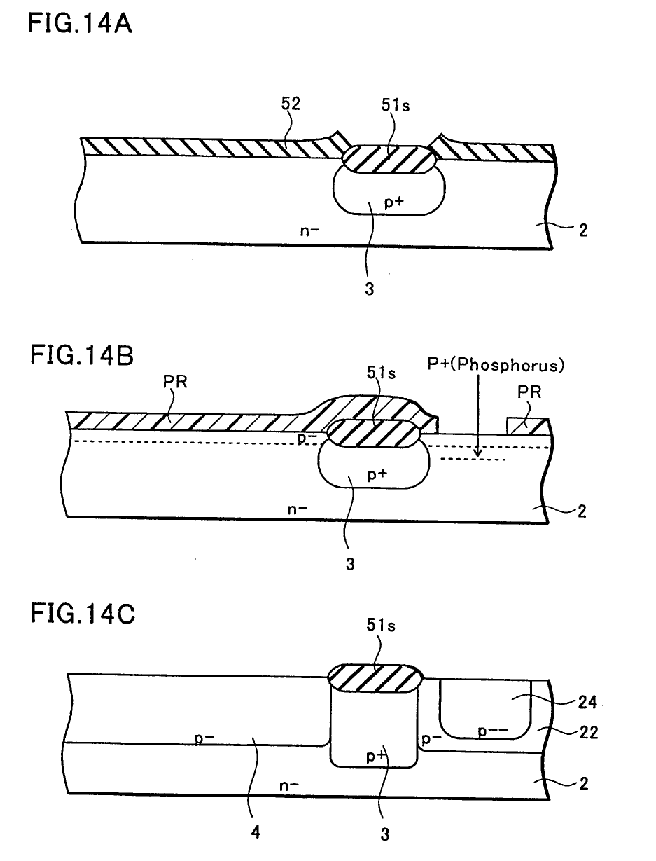

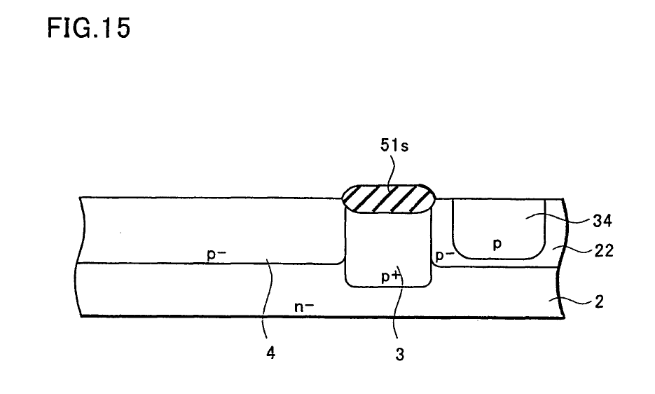

Next, with reference to FIGS. 14A through FIG. 15, manufacturing methods of second and third embodiments of the present invention will be described. Note that description of overlapping points between the first embodiment and the second and third embodiments will be omitted.

First step (FIGS. 14A to 14C): forming a guard ring, a channel layer and a peripheral region as in the case of the first embodiment.

A drain region 10 is formed by providing an n⁻ type semiconductor layer, which is formed, for example, by laminating an epitaxial layer, on an n⁺ type silicon semiconductor substrate 1.

Thereafter, an oxide film 51 and a nitride film 52 are provided on the entire surface, and a mask having an opening in the nitride film 52 is formed. Specifically, the opening is provided in a region of the nitride film 52 where a guard ring is to be formed by use of a resist PR. Subsequently, p-type impurities (for example, boron (B)) are ion-implanted by an injection energy of 50 KeV and a dose of 1E15 to 2E15 cm⁻². After removing the resist PR, heat treatment is performed to form a LOCOS oxide film 51s in the opening, and boron is diffused to form a guard ring 3 (FIG. 14).

Furthermore, the nitride film 52 is removed, and boron (B+), for example, is ion-implanted into the entire surface by an injection energy of 50 KeV and a dose of 1E13 to 3E13 cm⁻².

Thereafter, a mask made of a resist PR is provided so as to expose only a part of a periphery of the guard ring 3. The exposed surface of the semiconductor layer 2 is counter-doped with n-type impurities (for example, phosphorus (P)) by an injection energy of 100 KeV and a dose of 1E13 to 2E13 cm⁻² (FIG. 14B).

Subsequently, heat treatment is performed at about 1100° C., and boron is diffused to form a channel layer 4 in a surface of the semiconductor layer 2 in an element part 21. In this event, a p-type peripheral region 22 which comes into contact with the guard ring 3 is simultaneously formed in an element peripheral part 20. The peripheral region 22 has approximately the same impurity concentration as that of the channel layer 4. Moreover, in the peripheral region 22, a first p-type region 24 having an impurity concentration lower (p⁻⁻) than that of the channel layer 4 is formed (FIG. 14C).

Thereafter, the second to fourth steps are performed as in the case of the first embodiment. Thus, a final structure shown in FIGS. 3A and 3B is obtained. In the element part 21, a pn junction is formed by the channel layer 4 and the n⁻ type semiconductor layer 2. Moreover, in the element peripheral part 20, an npn junction is formed by the substrate (not shown), the n⁻ type semiconductor layer 2, the peripheral region 22, the first p-type region 24 and a peripheral n-type region 23.

Moreover, FIG. 15 shows the manufacturing method of the third embodiment.

In FIG. 14B, boron (B+), for example, is ion-implanted into the entire surface by an injection energy of 50 KeV and a dose of 1E13 to 3E13 cm⁻².

Thereafter, a mask made of a resist PR is provided so as to expose only a part of a periphery of a guard ring 3. Subsequently, p-type impurities (for example, boron) are ion-implanted into the exposed surface of a semiconductor layer 2 by an injection energy of 50 KeV and a dose in the order of 1E13 cm⁻².

Thereafter, heat treatment is performed to form a second p-type region 34 having an impurity concentration (p) higher than that of a channel layer 4 in a peripheral region 22. Thus, an npn junction is formed in a element peripheral part 20.

Subsequently, the second to fourth steps are performed as in the case of the first embodiment. Thus, a final structure shown in FIG. 4 is obtained.

In the second and third embodiments, the impurity concentration of the peripheral region 22 is selected according to a breakdown voltage. Therefore, a desired breakdown voltage can be obtained without changing an impurity concentration profile of the channel layer 4, and a breakdown position can be guided to the element peripheral part 20.

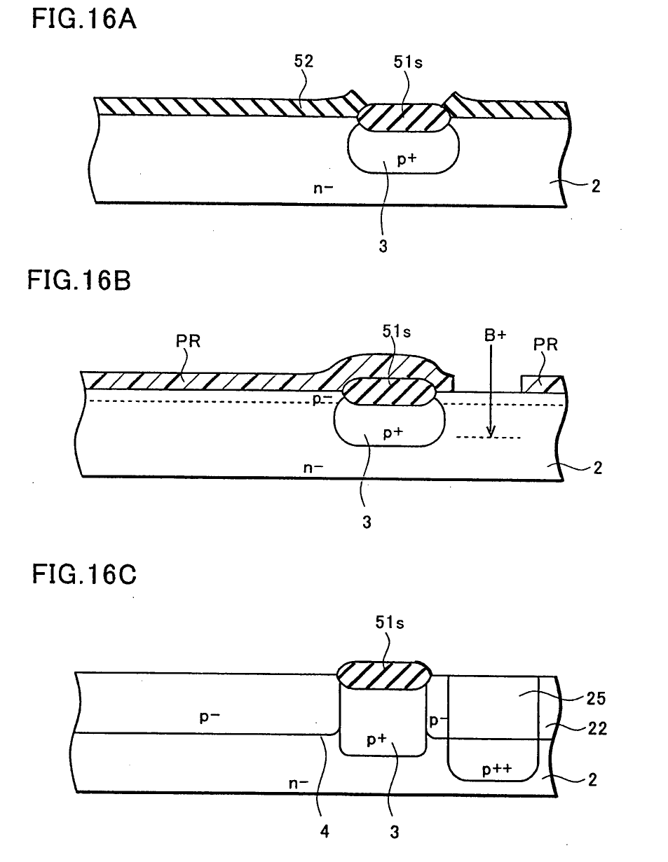

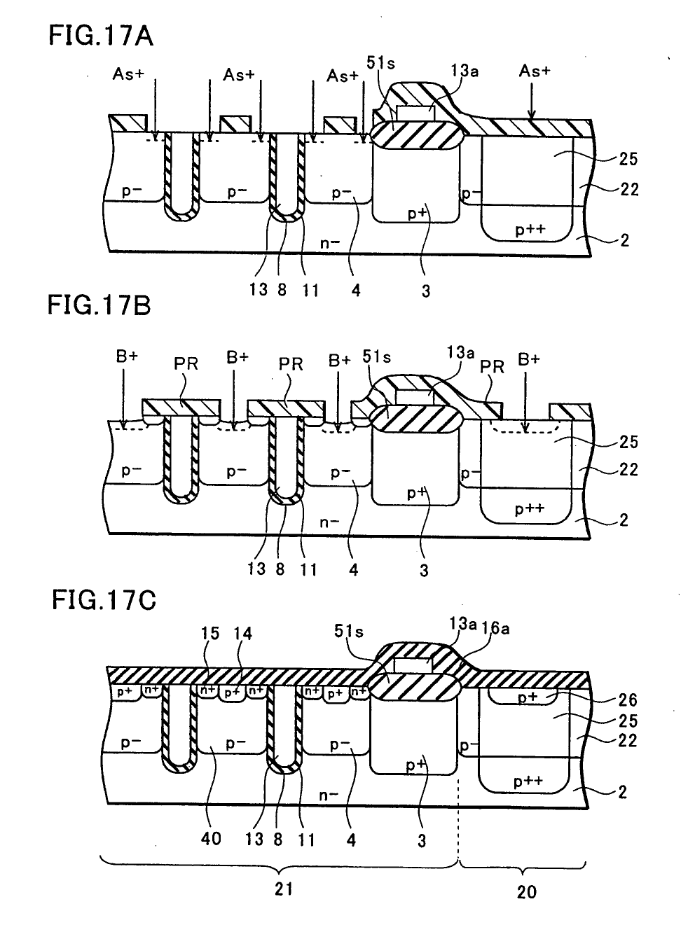

With reference to FIGS. 16 and 17, a manufacturing method of a fourth embodiment of the present invention will be described. Here, description of overlapping points between the first embodiment and the fourth embodiment will be omitted.

A method for manufacturing a semiconductor device of the fourth embodiment is a method for manufacturing a semiconductor device in which an element part having MOS transistors disposed therein and an element peripheral part surrounding a periphery of the element part are formed. The method includes the steps of: forming a channel layer having an opposite conductivity type on a surface of a one conductivity type semiconductor substrate to be a drain region of the element part, and forming a peripheral region having an opposite conductivity type in the element peripheral part; forming a gate electrode which comes into contact with the channel layer with an insulating film interposed therebetween; forming a source region having one conductivity type in a surface of the channel layer adjacent to the gate electrode; and forming a first electrode which comes into contact with the source region, and a second electrode which is connected to the peripheral opposite conductivity type region and is electrically connected to the first electrode.

First step: forming a channel layer having an opposite conductivity type on a surface of a one conductivity type semiconductor substrate to be a drain region of the element part, forming a peripheral region having an opposite conductivity type in the element peripheral part, and forming a peripheral opposite conductivity type region in the peripheral region, which is deeper than the peripheral region and has an impurity concentration higher than that of the peripheral region (FIGS. 16A to 16C).

A drain region 10 is formed by providing an n⁻ type semiconductor layer 2, which is formed, for example, by laminating an epitaxial layer, on an n⁺ type silicon semiconductor substrate 1 (not shown).

Thereafter, an oxide film 51 and a nitride film 52 are provided on the entire surface, and a mask having an opening in the nitride film 52 is formed. Specifically, the opening is provided in a region of the nitride film 52 where a guard ring is to be formed by use of a resist PR. Subsequently, p-type impurities (for example, boron (B)) are ion-implanted by an injection energy of 50 KeV and a dose of 1E15 to 2E15 cm⁻². After removing the resist PR, heat treatment is performed to form a LOCOS oxide film 51s in the opening, and boron is diffused to form a guard ring 3 (FIG. 16A).

Furthermore, the nitride film 52 is removed, and boron, for example, is ion-implanted into the entire surface by an injection energy of 50 KeV and a dose of 1E13 to 3E13 cm⁻².

Thereafter, a mask made of a resist PR is provided so as to expose only a part of a periphery of the guard ring 3. Subsequently, p-type impurities (for example, boron (B)) are ion-implanted into the exposed surface of the semiconductor layer 2 by an injection energy of 160 KeV and a dose of about 1E15 to 3E15 cm⁻² (FIG. 16B).

Subsequently, heat treatment is performed at about 1100° C., and boron is diffused to form a channel layer 4 in a surface of the semiconductor layer 2 of an element part 21. In this event, a p-type peripheral region 22 which comes into contact with the guard ring 3 is simultaneously formed in an element peripheral part 20. The peripheral region 22 has approximately the same impurity concentration as that of the channel layer 4. Moreover, in the peripheral region 22, a high-concentration (p⁺⁺) peripheral p-type region 25 is formed. Accordingly, the peripheral p-type region 25 which reaches the n⁻ type semiconductor layer 2 allows a part of the n⁻ type semiconductor layer 2 to become intrinsic. Thus, a tunnel junction approximate to a pin junction is formed by the substrate (not shown) and the peripheral p-type region 25 (FIG. 16C).

Second step: forming a gate electrode which comes into contact with the channel layer with an insulating film interposed therebetween. As in the case of the second step in the first embodiment, a trench 8, a gate oxide film 11, a gate electrode 13 and a connection part 13a are formed (see FIGS. 11A to 11C).

Third step (FIGS. 17A to 17C): forming a source region having one conductivity type in a surface of the channel layer adjacent to the gate electrode.

A mask made of a resist PR, in which a formation region of a source region is exposed, is formed, and n-type impurities (for example, arsenic (As)) are ion-implanted into the entire surface by an injection energy of 140 KeV and a dose of 5E15 to 6E15 cm⁻² (FIG. 17B).

Subsequently, a mask made of a resist PR, in which a formation region of a body region and a part of the peripheral region 22 are exposed, is formed, and p-type impurities (for example, boron (B)) are ion-implanted by an injection energy of 40 KeV and a dose of 2E15 to 5E15 cm⁻² (FIG. 17B).

Thereafter, a BPSG (boron phospho silicate glass) layer 16a to be an interlayer insulating film is deposited to have a thickness of about 6000 Å on the entire surface and is reflowed at about 900° C. This heat treatment diffuses the n-type impurities and the p-type impurities, respectively, to form a source region 15 adjacent to the trench 8, at the same time, a body region 14 between the source regions 15 is formed. Moreover, at the same time, a high-concentration (p⁺) source contact region 26 is formed in the surface of the peripheral region 22. Note that the ion implantations for the source region 15 and the body region 14 are not limited to the order described above but may be switched.

Thus, a region surrounded by the trench 8 becomes a cell of a MOS transistor 40, and the element part 21 in which a number of the cells are arranged is formed. In the element part 21, an np junction is formed by the channel layer 4 and the n-type semiconductor layer 2 (FIG. 17C).

Fourth step: forming a first electrode which comes into contact with the source region, and a second electrode which is connected to the peripheral opposite conductivity type region and is electrically connected to the first electrode.

As in the case of the fourth step in the first embodiment, a first source electrode 17, a gate connection electrode 18 and a second source electrode 19 are formed, and the first source electrode 17 and the second source electrode 19 are electrically connected to each other (see FIGS. 13A, 13B and 6).

The first source electrode 17 is connected to the second source electrode 19. Accordingly, when a predetermined drain voltage is applied to a drain electrode (not shown), the element part 21 operates as an np junction diode and the element peripheral part 20 operates as a tunnel diode approximate to a pin junction.

When a predetermined BVDS is reached, breakdown occurs in the element peripheral part 20 having a low breakdown voltage. This is because, as described above, the peripheral region 22 has approximately the same impurity concentration as that of the channel layer 4, and, under this condition, a tunnel junction is formed in the element peripheral part 20 and an np junction is formed in the element part 21.

Thereafter, in the state described above, the breakdown is terminated. Therefore, in this embodiment, by forming the tunnel junction in the element peripheral part 20, the breakdown occurs in the element peripheral part 20 from the beginning to the end. Specifically, since there will be no change in a breakdown position, there will also be no change in a BVDS.

Moreover, resistance of the tunnel junction can be reduced. Thus, the protection against overcurrent, overvoltage, static electricity and the like can be improved.

Moreover, as described above, the source contact region 26 can be formed only by changing the mask used for forming the body region 14. Furthermore, the semiconductor device can be manufactured only by adding the step of forming the peripheral p-type region 25 to the existing steps. Therefore, BVDS characteristics can be easily stabilized.

Moreover, if the impurity concentration of the peripheral region 22 is equal to or less than that of the channel layer 4, breakdown can be guided to the element peripheral part 20.

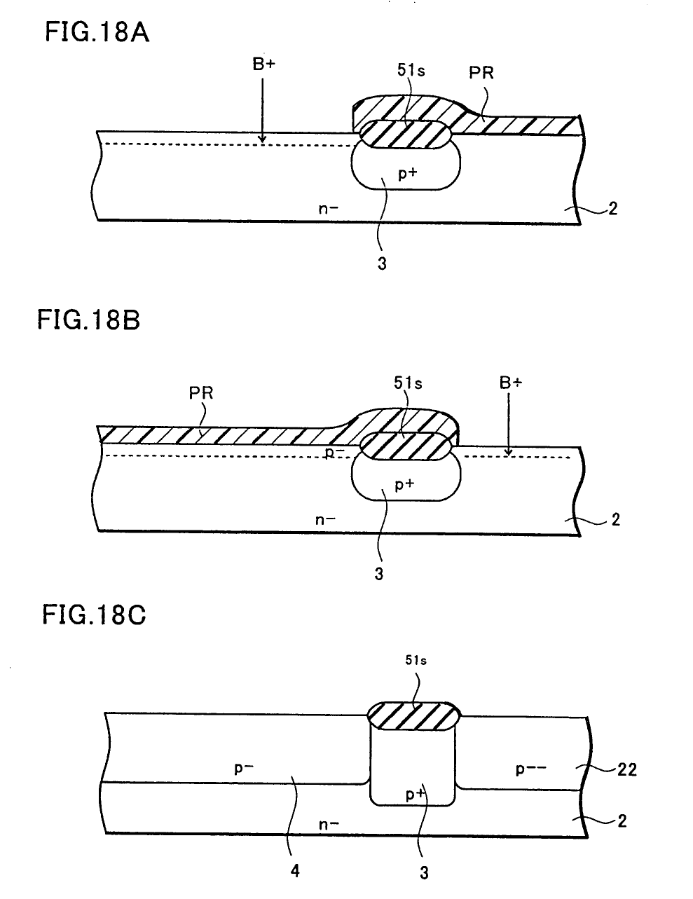

Each of FIG. 18A through FIG. 20C shows a case where, in each of the second to fourth embodiments, the peripheral region 22 is set to have an impurity concentration different from that of the channel layer 4 and is formed in a separate step. By forming the channel layer 4 and the peripheral region 22 in separate steps, respectively, a breakdown voltage of the element peripheral part 20 can be designed without changing an impurity concentration profile of the channel layer 4.

FIGS. 18A to 18C show the case of the second embodiment. First, as shown in FIG. 18A, a mask having an opening in a formation region of a channel layer is provided, and impurities of the channel layer are ion-implanted under a condition to obtain a desired threshold. Thereafter, as shown in FIG. 18B, a mask having an opening in a formation region of a peripheral region is provided, and impurities are ion-implanted under a condition to obtain a predetermined breakdown voltage. Note that, in this case, it is not required to perform counter doping, unlike the case of FIGS. 14A to 14C, and impurities having a concentration lower than that of the channel layer may be ion-implanted. Thereafter, heat treatment is performed to form the channel layer 4 and the peripheral region 22 as shown in FIG. 18C. Therefore, the step of forming the first opposite conductivity type region 24 is not required.

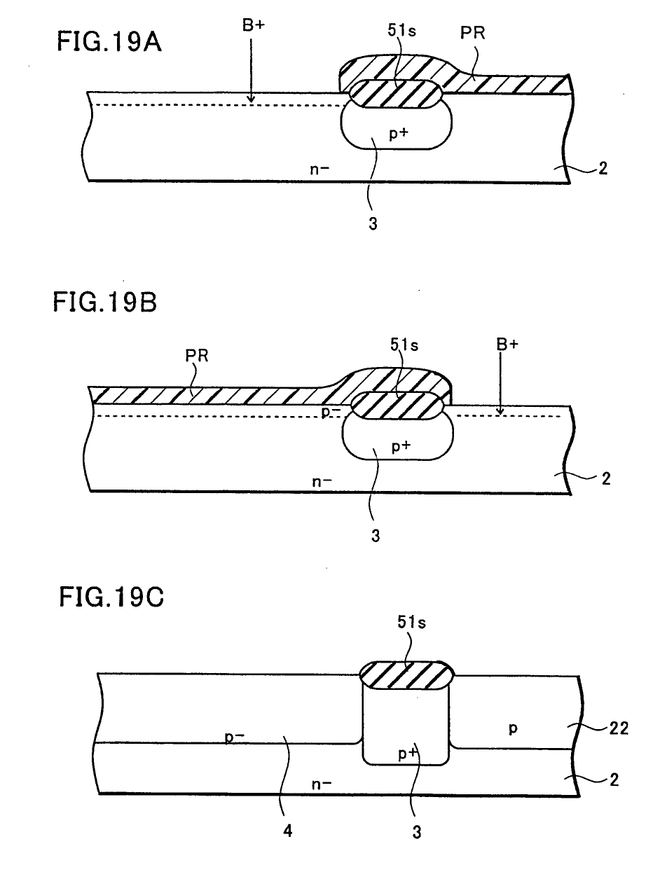

FIGS. 19A to 19C show the case of the third embodiment. Also in this case, impurities of a channel layer are ion-implanted (FIG. 19A), and impurities having a concentration higher than that of the channel layer are ion-implanted into a formation region of a peripheral region (FIG. 19B). Thereafter, heat treatment is performed to form the channel layer 4 and the peripheral region 22 (FIG. 19C). Therefore, the step of forming the second opposite conductivity type region 34 is not required.

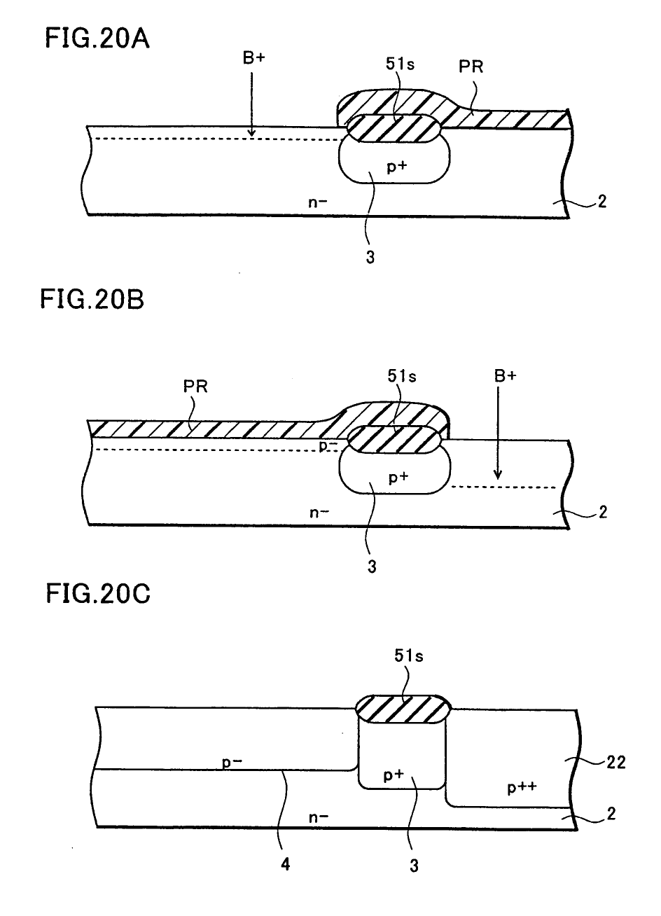

FIGS. 20A to 20C show the case of the fourth embodiment. Also in this case, impurities of a channel layer are ion-implanted (FIG. 20A), and impurities having a concentration higher than that of the channel layer are ion-implanted into a formation region of a peripheral region (FIG. 20B). Thereafter, heat treatment is performed to form the channel layer 4 and the peripheral region 22 deeper than the channel layer 4 (FIG. 20C). Therefore, the step of forming the peripheral opposite conductivity type region 25 is not required.

Note that, in FIGS. 18 to 20, the same effect can be achieved even if the ion implantations for the channel layer 4 and the peripheral region 22 are switched.

In the above first to fourth embodiments, description was given of the case where the peripheral region 22 which comes into contact with the guard ring 3 is provided outside the guard ring 3. However, the embodiments of the present invention are not limited to the above case. For example, the peripheral region 22 may be provided away from the guard ring 3 and the peripheral n-type region 23 or the peripheral p-type region 25 may be provided in the peripheral region 22.

Moreover, in the embodiments of the present invention, the description has been given by taking the n-channel MOSFET as an example. However, the embodiments of the present invention can be similarly applied to a MOSFET having a conductivity type reversed.

Furthermore, without being limited to the MOSFET, the embodiments of the present invention can be similarly applied to an insulated gate semiconductor element such as an IGBT which is provided an opposite conductivity type semiconductor layer under the substrate 1, and the similar effects can be achieved.

According to the embodiments of the present invention, first, the npn junction is formed in the element peripheral part, and the breakdown voltage of the element peripheral part is set lower than that of the element part. Thus, it is possible to guide breakdown to occur not in the element part but in the element peripheral part from the time of initial breakdown. Specifically, fluctuations in the value of the BVDS (creep phenomenon) can be suppressed, and breakdown voltage characteristics of the MOS transistor can be stabilized.

Secondly, by setting the impurity concentration of the peripheral region to be different from that of the channel layer, the breakdown voltage of the element peripheral part can be controlled. Therefore, the element peripheral part according to a predetermined breakdown voltage can be designed without changing the channel layer. Thus, the BVDS can be precisely controlled. Specifically, it is possible to realize device designing to set the channel layer as a predetermined threshold and to obtain a desired breakdown voltage in the element peripheral part.

Moreover, the impurity concentration of the peripheral region is set approximately the same as that of the channel layer, and the first or second opposite conductivity type region having an impurity concentration different from that of the peripheral region is provided in the peripheral region. Thus, the breakdown voltage of the element peripheral part can be controlled. Therefore, even if the peripheral region and the channel layer are formed in the same step, the element peripheral part according to a predetermined breakdown voltage can be designed.

Third, by forming the tunnel junction in the element peripheral part, the element peripheral part is set to have a resistance lower than that of the element part. Thus, it is possible to guide breakdown to occur in the element peripheral part from the time of initial breakdown.

Fourth, a high electrostatic breakdown strength is realized. By forming an npn junction (with a low junction breakdown voltage) which tends to cause breakdown or a p⁺/n⁻/n⁺ junction in the element peripheral part, it is possible to obtain I-V characteristics which set a resistance value close to 0 at the time of breakdown. Therefore, the breakdown current (overcurrent) Ios in the element peripheral part is increased. Thus, the device becomes less susceptible to breakdown.

Fifth, the peripheral region and the channel layer can be formed in the same step. Moreover, if the npn junction is formed in the element peripheral part, the peripheral n-type region and the source region can be formed in the same step. Therefore, the existing process flow can be utilized, and an increase in the number of masks and an increase in the steps of the process can be avoided.

Sixth, in the case where the tunnel junction is formed, the source contact region in the peripheral region and the body region can be formed in the same step. Therefore, the breakdown characteristics can be stabilized only by adding the step of forming the first peripheral p-type region. Thus, it is possible to provide a method for manufacturing a semiconductor device, which enables precise BVDS control.

What is claimed is:

1. A semiconductor device comprising:
a semiconductor substrate;
an element part that is part of the substrate and comprises a plurality of trench-type transistors, each of the transistors comprising a vertical cannel disposed between a source region formed in a surface of the substrate and a drain region that is disposed below the source region in the substrate;
an element peripheral part that is part of the substrate and surrounds the element part;
a peripheral impurity region that is disposed in the element peripheral part and has a same general conductivity type as the channel; and
an electrode that is disposed on the peripheral impurity region and is electrically connected to the source regions.

2. The semiconductor device of claim 1, further comprising a contact impurity region that has a same general conductivity type as the source regions and is disposed between the electrode and the peripheral impurity region.

3. The semiconductor device of claim 1, wherein an impurity concentration of the peripheral impurity region is determined so that under application of a voltage between the source and drain regions a breakdown occurs at the element peripheral part.

4. The semiconductor device of claim 1, wherein an impurity concentration of the peripheral impurity region is determined so that a breakdown voltage of the element peripheral part is lower than a breakdown voltage of the element part.

5. The semiconductor device of claim 1, wherein an impurity concentration of the peripheral impurity region is approximately equal to an impurity concentration of the channel.

6. The semiconductor device of claim 1, further comprising an additional impurity region that is disposed in the peripheral impurity region, has an impurity concentration lower than an impurity concentration of the peripheral impurity region and has the same general conductivity type as the channel.

7. The semiconductor device of claim 1, further comprising an additional impurity region that is disposed in the peripheral impurity region, has an impurity concentration higher than an impurity concentration of the peripheral impurity region and has the same general conductivity type as the channel.

8. The semiconductor device of claim 2, wherein an impurity concentration of the contact impurity region is approximately equal to an impurity concentration of the source region.

9. The semiconductor device of claim 1, wherein a resistance of the element peripheral part is lower than a resistance of the element part.

10. The semiconductor device of claim 1, further comprising an additional impurity region that is disposed in the peripheral impurity region, has an impurity concentration higher than an impurity concentration of the peripheral impurity region, has the same general conductivity type as the channel and is deeper than the peripheral impurity region.

11. The semiconductor device of claim 1, wherein an impurity concentration of the peripheral impurity region is higher than an impurity concentration of the channel, and the peripheral impurity region is deeper than the channel layer.

12. The semiconductor device of claim 1, wherein the element part comprises a guard ring that has the same general conductivity type as the channel and is disposed at an edge portion of the element part.

13. A method of manufacturing a semiconductor device, comprising:
providing a semiconductor substrate of a first general conductivity type;
defining an element part of the substrate in which a plurality of transistors are formed;
forming an impurity region of a second general conductivity type in the substrate around the element part; and
forming a peripheral electrode that is disposed on the impurity region and connected to electrodes of the transistors.

14. The method of claim 13, further comprising forming a contact impurity region that is disposed between the peripheral electrode and the impurity region.

15. The method of claim 13, further comprising forming a channel layer on the substrate, forming trenches in the channel layer, filling the trenches with a conducting material and forming source regions in the surface of the substrate so that the transistors are made.

16. The method of claim 13, further comprising forming an additional impurity region of the second general conductivity type in the impurity region so as to have an impurity concentration lower than the impurity region.

17. The method of claim 13, further comprising forming an additional impurity region of the second general conductivity type in the impurity region so as to have an impurity concentration higher than the impurity region.

18. The method of claim 13, wherein an impurity concentration of the impurity region is determined so that a breakdown voltage of the impurity region is lower than a breakdown voltage of the element part.

19. The method of claim 13, further comprising forming an additional impurity region of the second general conductivity type in the impurity region so as to have an impurity concentration higher than the impurity region and to have a depth larger than the impurity region.

20. The method of claim 15, wherein the formation of the channel layer is such that an impurity concentration of the impurity region is higher than an impurity concentrations of the channel layer and a depth of the impurity region is larger than the channel layer.

21. The method of claim 13, wherein the formation of the impurity region is such that a resistance of the impurity region is lower than a resistance of the element part.

22. The method of claim 15, wherein the impurity region and the channel layer are formed in a same process step.
